(19) United States
(12) Patent Application Publication
(10) Pub. No.: US 2012/0325300 A1
(43) Pub. Date: Dec. 27, 2012

(54) INVERTED METAMORPHIC (IMM) SOLAR CELL SEMICONDUCTOR STRUCTURE AND LASER LIFT-OFF METHOD FOR THE SAME

(75) Inventors: Chan-Wei Yeh, Longtan Township (TW); Chih-Hung Wu, Longtan Township (TW); Min-De Yang, Longtan Township (TW); Yun-Heng Tseng, Longtan Township (TW)

(73) Assignee: INSTITUTE OF NUCLEAR ENERGY RESEARCH, ATOMIC ENERGY COUNCIL, EXECUTIVE YUAN, Longtan Township (TW)

(21) Appl. No.: 13/337,895

(22) Filed: Dec. 27, 2011

(30) Foreign Application Priority Data
Jun. 21, 2011 (TW) 100121674

(51) Int. Cl. H01L 31/06; H01L 31/18

(52) U.S. Cl. 136/255; 438/93; 257/E31.019

(57) ABSTRACT

An inverted metamorphic (IMM) solar cell semiconductor structure for use of a laser lift-off (LLO) process using external laser is introduced. The IMM solar cell semiconductor structure includes a substrate layer, a sacrifice layer, a plurality of bandgap layers, and a handle layer. The sacrifice layer, formed on the substrate layer, is made of a material containing a III-V compound. The bandgap layers, formed on the sacrifice layer, are for producing movements of electronic holes according to an absorbed extrinsic light wavelength. The handle layer is formed on the bandgap layers. Laser penetrates the substrate layer to fall on the sacrifice layer, such that the bandgap layers are lifted off by the sacrifice layer, thereby resulting in a high-efficiency IMM solar cell. A LLO laser lift-off method for the IMM solar cell semiconductor is further provided.

### CROSS-REFERENCE TO RELATED APPLICATION

This non-provisional application claims priority under 35 U.S.C. §119(a) on Patent Application No(s). 100121674 filed in Taiwan, R.O.C. on Jun. 21, 2011, the entire contents of which are hereby incorporated by reference.

### FIELD OF THE INVENTION

The present invention relates to an inverted metamorphic (IMM) solar cell semiconductor structure and a laser lift-off (LLO) method for the same, and more particularly, to semiconductor structure that lifts off a substrate layer from a plurality of bandgap layers by using extrinsic laser.

### BACKGROUND OF THE INVENTION

In the prior art, a gallium nitride (GaN) light-emitting diode (LED) adopts sapphire as a substrate material due to limitations of epitaxy. However, a sapphire substrate has a rather unsatisfactory heat conductivity, which severely depreciates light-emitting efficiency of the LED. Therefore, the sapphire substrate is removed and is replaced by a substrate made of other materials having a better heat conductivity.

There are three conventional methods for removing the sapphire substrate. The first method is removing the sapphire by abrasion, the second is by etching, and the third is by laser. Among the three methods, removing the sapphire substrate by laser is the most effective.

However, the three methods above are only applicable to an LED comprising GaN and a sapphire substrate. For an IMM solar cell that is becoming increasingly prevalent, there is a need for a material that matches a sacrifice layer and suitable for a gallium arsenide (GaAs) substrate for overcoming issues associated with the conventional manufacturing of a solar cell.

### SUMMARY OF THE INVENTION

It is an object of the present invention to provide an inverted metamorphic (IMM) solar cell semiconductor structure for use of a laser lift-off (LLO) process using external laser.

It is another object of the present invention to provide an IMM solar cell semiconductor structure for providing a high-efficiency IMM solar cell.

It is yet another object of the present invention to provide a laser lift-off method for an IMM solar cell semiconductor structure, so as to lift-off a substrate layer from the IMM solar cell semiconductor structure.

To achieve the above objects, an IMM solar cell semiconductor structure is provided according an aspect of the present invention. The IMM solar cell semiconductor structure, for use of an LLO process using external laser, comprises a substrate layer, a sacrifice layer, a plurality of bandgap layers and a handle layer. The sacrifice layer, formed on the substrate layer, is made of a material containing a III-V compound. The bandgap layers, formed on the sacrifice layer, are for producing movements of electronic holes according to an absorbed extrinsic light wavelength. The handle layer is formed on the bandgap layers.

A laser lift-off method for an IMM solar cell semiconductor structure is further provided according to another aspect of the present invention. The method comprises: a) forming a sacrifice layer on a substrate layer, the sacrifice layer being a made of a material containing a III-V compound and having a bandgap smaller than a bandgap of the substrate layer; b) forming a plurality of bandgap layers on the sacrifice layer, and forming a handle layer on the bandgap layers; and c) rendering an external laser entering the sacrifice layer from the substrate layer, penetrating the substrate layer and being absorbed by the sacrifice layer, such that the bandgap layers are lifted off by the sacrifice layer.

Compared with the prior art, the IMM solar cell semiconductor structure and the LLO method disclosed by the present invention, by flexibly adjusting a lattice constant and an energy bandgap of the sacrifice layer made of a material containing a III-V compound, are capable of matching the substrate layer also containing the same III-V compound, and removing the substrate layer from the IMM solar cell by using external laser, thereby increasing efficiency of the solar cell.

### BRIEF DESCRIPTION OF THE DRAWINGS

FIGS. 1a and 1b are schematic diagrams of an IMM solar cell semiconductor structure according to an embodiment of the present invention;

FIG. 2 is a relationship diagram between an energy bandgap and a lattice constant of the sacrifice layer in FIG. 1;

FIG. 3 is a schematic diagram illustrating operations of the substrate layer, the sacrifice layer and a wavelength corresponding to a bandgap of laser in FIG. 1;

FIG. 4 is a flowchart a of a laser lift-off method for an IMM solar cell semiconductor structure according to an embodiment of the present invention; and

FIG. 5 is a flowchart a of a laser lift-off method for an IMM solar cell semiconductor structure according to another embodiment of the present invention.

### DETAILED DESCRIPTION OF THE PREFERRED EMBODIMENTS

The present invention will become more readily apparent to those ordinarily skilled in the art after reviewing the following detailed description and accompanying drawings.

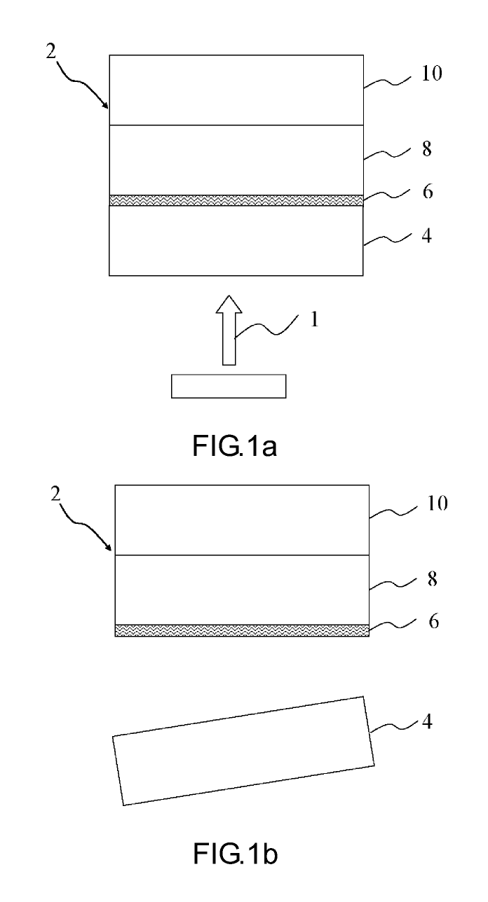

FIGS. 1a and 1b show schematic diagrams of an IMM solar cell semiconductor structure according to an embodiment of the present invention. In FIG. 1a, an IMM solar cell semiconductor structure 2 is for use of a laser lift-off (LLO) process by external laser 1. For example, the external laser 1 is neodymium yttrium aluminum garnet (Nd: AG) laser, with a wavelength of 1064 nm and a corresponding power density of 600 mJ/cm².

The IMM solar cell semiconductor structure 2 comprises a substrate layer 4, a sacrifice layer 6, bandgap layers 8 and a handle layer 10. The substrate layer 4 provides a base layer required for developing epitaxy for the solar cell semiconductor, and may be made of a material containing a III-V compound, e.g., GaAs.

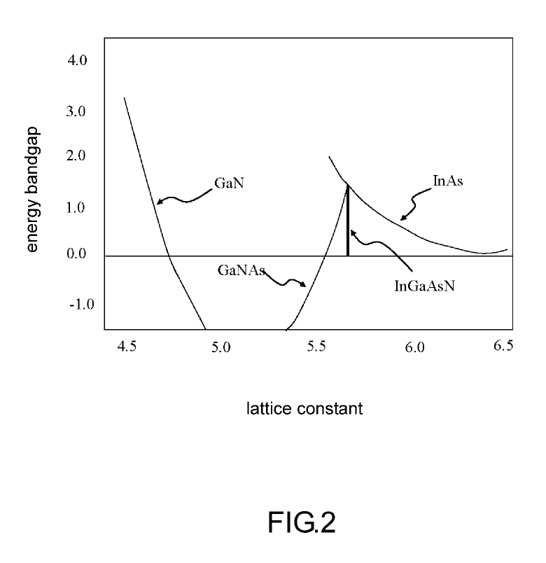

The sacrifice layer 6 is formed on the substrate layer 4, and is made of a material containing a III-V compound. Thus, the sacrifice layer 6 is at least one compound containing indium, gallium, arsenic and/or nitrogen. For example, the sacrifice layer 4 is made of nitrogen indium gallium arsenide (InGaAsN). FIG. 2 shows a relationship diagram between an energy bandgap and a lattice constant of the sacrifice layer comprising InGaAsN. As observed from FIG. 2, the InGaAsN contains a substrate GaAs, which is doped with indium to increase the lattice constant and reduce the energy bandgap, and also doped with nitrogen to reduce both the lattice constant and the energy bandgap. That is to say, by adjusting a doping ratio of the indium and the nitrogen, an appropriate sacrifice layer 6 matching the substrate layer 4 can be determined. For example, in an embodiment, the lattice constant stays fixed while the energy bandgap is flexibly adjustable by a predetermined doping ratio of the indium and the nitrogen.

A ratio of the nitrogen in the sacrifice layer is 10% to 20% of the compound making up the material of the sacrifice layer 6; a thickness of epitaxy of the sacrifice layer 6 may be smaller than a thickness of the substrate layer.

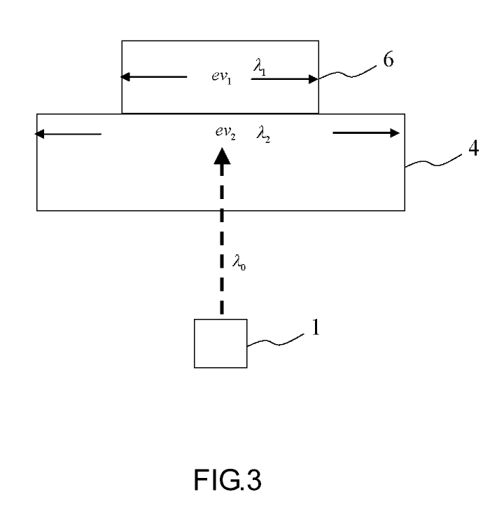

In order to lift-off the substrate layer 4 from the bandgap layers 8 by the sacrifice layer 6, a wavelength λ₁ corresponding to a bandgap ev₁ of the sacrifice layer 6 is greater than a wavelength λ₀ of the laser 1, and the wavelength of the laser 1 is greater than a wavelength corresponding to a bandgap ev₂ of the substrate layer 4, as shown in FIG. 3. A relation between the wavelength and the bandgap is λ=1.24/ev. In an embodiment, the wavelength of the substrate layer 4 is 890 nm. In other words, the wavelength of the laser 1 is between the wavelength corresponding to the bandgap of the sacrifice layer 6 and the wavelength corresponding to the bandgap of the substrate layer 4.

The bandgap and the wavelength are configured in a way that the wavelength and energy of the laser 1 enter from the substrate layer 4 to fall on the sacrifice layer 6 to be directly absorbed by the sacrifice layer 6 (i.e., the laser 1 is not absorbed by the substrate layer 4), such that the sacrifice layer 6 comprising a III-V compound decomposes into vapor and liquid. The vapor becomes a gas and dissipates, whereas the liquid remains between the sacrifice layer 6 and the substrate layer 4. More specifically, the laser 1 heats the sacrifice layer 6 to break a link between the substrate layer 4 and the sacrifice layer 6, as shown in FIG. 1b.

The bandgap layers 8, formed on the sacrifice layer 6, are for producing movements of electronic holes according to an absorbed extrinsic light wavelength (e.g., a sunlight light source). The bandgap layers 8 may be consisted of materials having different bandgaps (or electron volts, e.g., indium gallium phosphide (InGaP) and GaAs.

The handle layer 10 is formed on the bandgap layers 8. In practice, after lifting off the substrate layer 4 using the laser 1, the IMM solar cell semiconductor structure 2 is inverted such that the handle layer 10 originally located at the uppermost side becomes the lowermost side, and thus an inverted epitaxial structure is adopted as an illustrative example. In another embodiment, the IMM solar cell semiconductor structure 2 may be a non-inverted epitaxial structure.

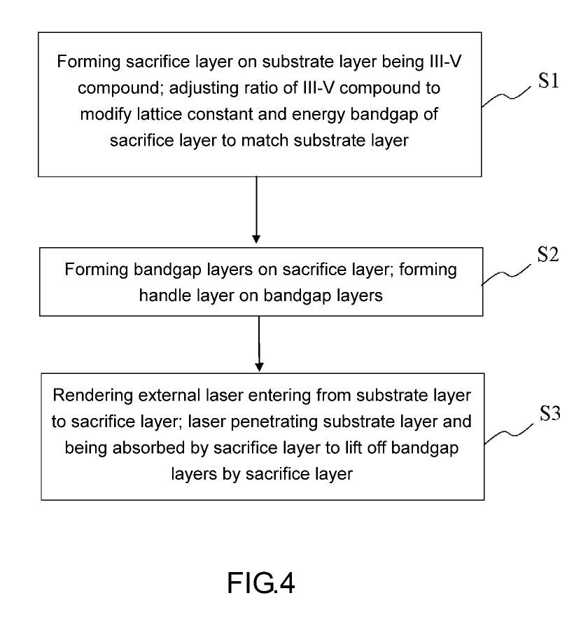

FIG. 4 shows a flowchart of an LLO method for an IMM solar cell semiconductor structure according to an embodiment of the present invention. In FIG. 4, the LLO method for an IMM solar cell semiconductor structure begins with Step S1 to form a sacrifice layer on a substrate layer. The sacrifice layer is made of a material containing a III-V compound, and has a bandgap smaller than a bandgap of the substrate layer. By adjusting a ratio of the III-V compound, a lattice constant and an energy bandgap of the sacrifice layer may be modified to match the substrate layer.

In Step S2, a plurality of bandgap layers are formed on the sacrifice layer, and a handle layer is then formed on the bandgap layers.

In Step S3, external laser enters via the substrate layer to fall on the sacrifice layer. The laser penetrates the substrate layer and is absorbed by the sacrifice layer such that that the bandgap layers are lifted off by the sacrifice layer. A wavelength corresponding to the bandgap of the sacrifice layer is greater than a wavelength of the laser, and the wavelength of the laser is greater than the bandgap of the substrate layer.

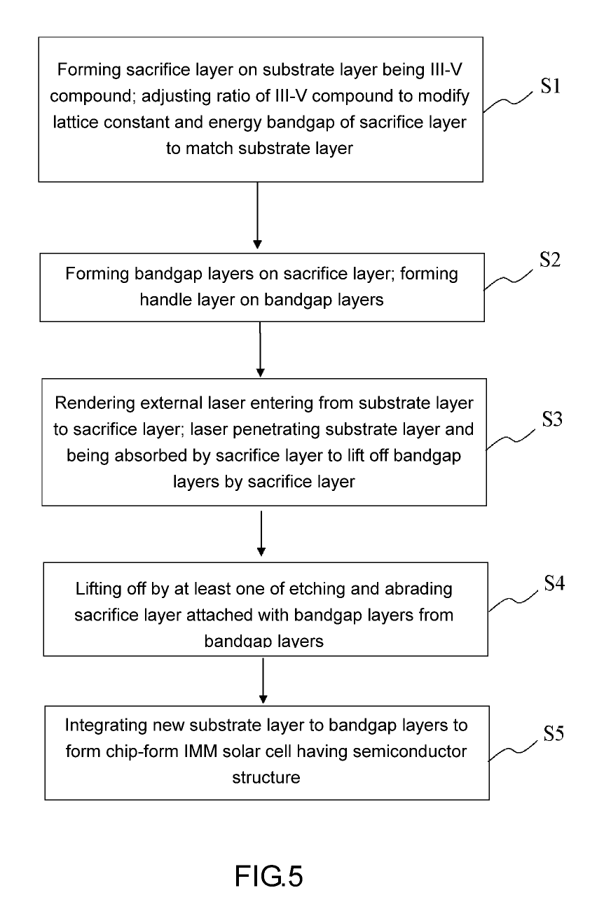

FIG. 5 shows a flowchart of an LLO method for an IMM solar cell semiconductor structure according to another embodiment of the present invention. In FIG. 5, apart from Steps S1 to S3, the LLO method for an IMM solar cell semiconductor structure further comprises Step S4 for lifting off the sacrifice layer still attached to the bandgap layers from the bandgap layers by at least one of etching and abrading, so as to obtain an IMM solar cell semiconductor structure that is free of residual sacrifice layer while comprising the bandgap layers and the substrate layer.

The LLO method for an IMM solar cell semiconductor structure may further comprise Step S5 for integrating a new substrate layer on the bandgap layers to form a chip-form IMM solar cell having the semiconductor structure.

With description of the above embodiments, it is illustrated that the IMM solar cell semiconductor structure and the LLO method for the same, by flexibly adjusting a lattice constant and an energy bandgap of the sacrifice layer made of a material containing a III-V compound, are capable of matching the substrate layer also containing the same III-V compound, and removing the substrate layer from the IMM solar cell by using external laser, thereby increasing efficiency of the solar cell.

While the invention has been described in terms of what is presently considered to be the most practical and preferred embodiments, it is to be understood that the invention is illustrative and needs not to be limited to the above embodiments. On the contrary, it is intended to cover various modifications and similar arrangements included within the spirit and scope of the appended claims which are to be accorded with the broadest interpretation so as to encompass all such modifications and similar structures.

What is claimed is:

1. An inverted metamorphic (IMM) solar cell semiconductor structure, for use of a laser lift-off (LLO) process by external laser, comprising:
a substrate layer;
a sacrifice layer, formed on the substrate layer, being made of a material comprising a III-V compound;
a plurality of bandgap layers, formed on the sacrifice layer, for producing movements of electronic holes according to an absorbed extrinsic light wavelength; and
a handle layer, formed on the bandgap layers.

2. The semiconductor structure as claimed in claim 1, wherein the substrate layer is made of gallium arsenide (GaAs).

3. The semiconductor structure as claimed in claim 2, wherein the sacrifice layer is made of a material comprising a compound of at least one of indium, gallium, arsenic and nitrogen.

4. The semiconductor structure as claimed in claim 3, wherein the sacrifice layer is made of nitrogen indium gallium arsenide (InGaAsN).

5. The semiconductor structure as claimed in claim 4, wherein a ratio of the nitrogen and the indium adjusts a lattice constant and an energy bandgap of the sacrifice layer to match the substrate layer.

6. The semiconductor structure as claimed in claim 5, wherein a ratio of the nitrogen in the sacrifice layer is 10% to 20% of the compound.

7. The semiconductor structure as claimed in claim 5, wherein a wavelength corresponding to a bandgap of the sacrifice layer is greater than a wavelength of the laser, and the wavelength of the laser is greater than a wavelength corresponding to a bandgap of the substrate layer.

8. The semiconductor structure as claimed in claim 7, wherein the wavelength of the substrate layer is 890 nanometers (nm).

9. The semiconductor structure as claimed in claim 8, wherein the laser is neodymium yttrium aluminum garnet (Nd:AG) laser.

10. The semiconductor structure as claimed in claim 9, wherein the wavelength of the laser is 1064 nm, and a power density corresponding to the laser is 600 microjoules/cm².

11. A laser lift-off (LLO) method for an IMM solar cell semiconductor structure, comprising:
forming a sacrifice layer on a substrate layer, the sacrifice layer being a material made of a III-V compound and having a bandgap smaller than a bandgap of the substrate;
forming a plurality of bandgap layers on the sacrifice layer, and forming a handle layer on the bandgap layers; and
rendering external laser entering from the substrate layer to the sacrifice layer, the laser penetrating substrate layer and being absorbed by the sacrifice layer to lift off the bandgap layers by the sacrifice layer.

12. The LLO method as claimed in claim 11, wherein a wavelength corresponding to the bandgap of the sacrifice layer is greater than a wavelength of the laser, and the wavelength of the laser is greater than a wavelength corresponding to the bandgap of the substrate layer.

13. The LLO method as claimed in claim 12, wherein a ratio of the III-V compound is adjusted to modify a lattice constant and an energy bandgap of the sacrifice layer to match the substrate layer.

14. The LLO method as claimed in claim 13, further comprising at least one of etching and abrading the sacrifice layer attached with the bandgap layers from the bandgap layers.

15. The LLO method as claimed in claim 14, further comprising integrating a new substrate layer on the bandgap layers to form a chip-form IMM solar cell having the semiconductor structure.
